(19) United States
(12) Patent Application Publication
(10) Pub. No.: US 2026/0130133 A1
(43) Pub. Date: May 7, 2026

(54) RUTHENIUM SIDEWALL COATING ON ORGANIC PLANARIZATION LAYER

(71) Applicant: INTERNATIONAL BUSINESS MACHINES CORPORATION, ARMONK, NY (US)

(72) Inventors: Luxherta Buzi, Chappaqua, NY (US); Robert L. Bruce, White Plains, NY (US)

(21) Appl. No.: 18/940,423

(22) Filed: Nov. 7, 2024

(51) Int. Cl. H10N 70/00; H10B 63/10; H10N 70/20

(52) U.S. Cl. CPC H10N 70/841; H10B 63/10; H10N 70/011; H10N 70/231

(57) ABSTRACT

Provided are devices and methods relating to forming an electronic device, including providing a ruthenium (Ru) layer on a device layer. An organic planarization layer is formed on the Ru layer, wherein the Ru layer is positioned between the device layer and the organic planarization layer. One or more etching operations are performed to etch part of the organic planarization layer to form a remaining portion of the organic planarization layer and to etch part of the Ru layer to form a remaining portion of the Ru layer, wherein the etching operation to etch part of the Ru layer further includes forming a coating including Ru from the Ru layer on a sidewall of the remaining portion of the organic planarization layer.

### BACKGROUND OF THE INVENTION

### 1. Field of the Invention

Provided are devices and methods related to semiconductor devices and their fabrication including forming a sidewall coating on an organic planarization layer.

### 2. Description of the Related Art

The formation of semiconductor devices often involves processing a stack of layers including active regions and pathways for making electrical connection to the active regions. Examples of such semiconductor devices include non-volatile random access memory, such as 3D cross-point memory. These devices may utilize phase change materials in the memory cells. In phase change memory cells, information is stored in materials that can be manipulated into different phases, e.g., the amorphous phase and the crystalline phase. These phases may be used for bit storage of binary values because they have detectable differences in electrical resistance. The amorphous phase tends to have a higher electrical resistance than the crystalline phase. Semiconductor devices such as phase change memory (PCM) devices may be formed in a plasma chamber using suitable gases to process the various layers in the device. A number of masking and etching operations may be carried out to form the device.

### SUMMARY

Provided are methods for forming an electronic device and devices formed therefrom. One method for forming an electronic device includes providing a layer comprising ruthenium on a device layer. An organic planarization layer is formed on the layer comprising ruthenium, wherein the layer comprising ruthenium (Ru) is positioned between the device layer and the organic planarization layer. One or more etching operations are performed to etch part of the organic planarization layer to form a remaining portion of the organic planarization layer and to etch part of the layer comprising ruthenium to form a remaining portion of the layer comprising ruthenium. The one or more etching operations to etch part of the layer comprising ruthenium further includes forming a coating comprising ruthenium from the layer comprising ruthenium on a sidewall of the remaining portion of the organic planarization layer.

Also provided is a method for forming an electronic device, including providing a layer comprising ruthenium on a device layer and forming an electrode layer on the layer comprising ruthenium. The method also includes forming an organic planarization layer on the electrode layer, and etching part of the organic planarization layer to form a remaining portion of the organic planarization layer. The method further includes etching part of the electrode layer and part of the layer comprising ruthenium to form a remaining portion of the electrode layer and a remaining portion of the layer comprising ruthenium, wherein the etching part of the electrode layer and part of the layer comprising ruthenium further comprises forming a coating comprising ruthenium from the layer comprising ruthenium on a sidewall of the remaining portion of the organic planarization layer.

Also provided is a phase change memory device including a phase change memory material. The device also includes an electrode layer on the phase change memory material, the electrode material layer including a sidewall coating comprising ruthenium.

### BRIEF DESCRIPTION OF THE DRAWINGS

FIGS. 1A-1D illustrate operations for processing layers to form an electronic device, in accordance with certain embodiments.

FIG. 2 illustrates an electronic device including a top electrode and a bottom electrode, and further including a phase change memory material positioned therebetween, in accordance with certain embodiments.

FIG. 3 illustrates a flowchart of operations in accordance with certain embodiments.

FIG. 4 illustrates a flowchart of operations in accordance with certain embodiments.

### DETAILED DESCRIPTION

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, and/or to enable others of ordinary skill in the art to understand the embodiments disclosed herein.

The description herein provides examples of embodiments of the invention, and variations and substitutions may be made in other embodiments. Several examples will now be provided to further clarify various embodiments of the present disclosure.

Example 1 is a method for forming an electronic device. The method comprises providing a layer comprising ruthenium on a device layer. An organic planarization layer is formed on the layer comprising ruthenium, wherein the layer comprising ruthenium is positioned between the device layer and the organic planarization layer. One or more etching operations are performed to etch part of the organic planarization layer to form a remaining portion of the organic planarization layer and to etch part of the layer comprising ruthenium to form a remaining portion of the layer comprising ruthenium. The one or more etching operations to etch part of the layer comprising ruthenium further includes forming a coating comprising ruthenium from the layer comprising ruthenium on a sidewall of the remaining portion of the organic planarization layer. Thus, embodiments advantageously allow for the use of the sidewall coated remaining portion of the organic planarization layer as a mask during subsequent processing operations, which lessens the need for forming an additional mask and increases processing efficiency.

Example 2: The limitations of any of claims 1 and 3-7 may optionally include forming an electrode layer on the ruthenium layer so that the electrode layer is positioned between the layer comprising ruthenium and the organic planarization layer, and etching the electrode layer. The coating comprising ruthenium on the sidewall of the remaining portion of the organic planarization layer further includes a material of the electrode layer. Thus, embodiments allow for the formation of the sidewall coating on the remaining portion of the organic planarization layer to further include the material of the electrode layer. The sidewall coating having multiple materials may provide desirable properties relating to mask retention during subsequent operations.

Example 3: The limitation of any of claims 1-2 and 4-7, further comprising forming the coating comprising ruthenium on a sidewall of the electrode layer. Thus embodiments allow for the formation of the sidewall coating to extend on the remaining portion of the electrode layer, which may provide desirable properties relating to mask retention during subsequent operations where the remaining organic planarization layer and remaining electrode layer are used as a mask.

Example 4: The limitation of any of claims 1-3 and 5-7, further comprising wherein the coating comprising ruthenium has a thickness in a range of 1 angstrom to 10 angstroms. Thus embodiments allow for the formation of a thin coating that protects the sidewall and enhances the ability of the existing layers to be used as a mask during subsequent processing operations.

Example 5: The limitation of any of claims 1-4 and 6-7, further comprising forming a barrier layer between the device layer and the layer comprising ruthenium. Thus embodiments allow for the formation of a barrier layer to protect underlying layers during processing operations.

Example 6: The limitation of any of claims 1-5 and 7, further comprising wherein the barrier layer comprises carbon. Thus, embodiments allow for the use of carbon as an effective barrier layer material between the layer comprising ruthenium and the underlying layers.

Example 7: The limitation of any of claims 1-6, further comprising wherein the electrode layer comprises tantalum nitride. Thus, embodiments allow for the use of tantalum nitride as an effective electrode layer material.

Example 8 is a method for forming an electronic device, comprising providing a layer comprising ruthenium on a device layer and forming an electrode layer on the layer comprising ruthenium. An organic planarization layer is formed on the electrode layer. The method also includes etching part of the organic planarization layer to form a remaining portion of the organic planarization layer. The method also includes etching part of the electrode layer and part of the layer comprising ruthenium to form a remaining portion of the electrode layer and a remaining portion of the layer comprising ruthenium. The etching part of the electrode layer and part of the layer comprising ruthenium further comprises forming a coating comprising ruthenium from the layer comprising ruthenium on a sidewall of the remaining portion of the organic planarization layer. Thus, embodiments advantageously allow for the use of the sidewall coated organic planarization layer as a mask during subsequent processing operations, which lessens the need for forming an additional mask and increases processing efficiency.

Example 9: The limitation of any of claims 8 and 10-14, further comprising wherein the etching part of the electrode layer and part of the layer comprising Ru further comprises forming the coating on the sidewall of the remaining portion of the organic planarization layer to include a material from the electrode layer. Thus, embodiments allow for the formation of the sidewall coating on the remaining portion of the organic planarization layer to further include the material of the electrode layer. The sidewall coating having multiple materials may provide desirable properties relating to mask retention during subsequent operations.

Example 10: The limitation of any of claims 8-9 and 11-14, further comprising forming the coating comprising ruthenium on a sidewall of the remaining portion of the electrode layer. Thus embodiments allow for the formation of the sidewall coating to extend on the remaining portion of the electrode layer, which may provide desirable properties relating to mask retention during subsequent operations where the remaining organic planarization layer and remaining electrode layer are used as a mask.

Example 11: The limitation of any of claims 8-10 and 12-14, further comprising forming the coating comprising Ru to have a thickness in a range of from 1 angstrom to 10 angstroms. Thus embodiments allow for the formation of a thin coating that protects the sidewall and enhances the ability of the existing layers to be used as a mask during subsequent processing operations.

Example 12: The limitation of any of claims 8-11 and 13-14, further comprising wherein the device layer comprises a barrier layer on a phase change memory material layer. Thus embodiments allow for the formation of a barrier layer to protect underlying layers during processing operations.

Example 13: The limitation of any of claims 9-12 and 14, further comprising wherein the etching part of the electrode layer and part of the layer comprising ruthenium comprises performing a plamsa etching operation including a chemical reaction and physical sputtering. Thus, embodiments permit an etching operation that includes both a chemical reaction to remove material and a physical bombardment that ejects material from one surface and deposits a quantity of the ejected material onto the sidewalls of at least the organic planarization layer to form a protective layer, enabling its effective use as a mask.

Example 14: The limitation of any of claims 9-13, further comprising wherein the plasma etching operation includes using a plurality of gases including chlorine, oxygen, and argon. Thus, embodiments with the recited gases permit chemical reaction and physical sputtering to occur, while also providing a desirable passivating gas presence during at least some processing operations.

Example 15 is a phase change memory device comprising a phase change memory material and an electrode layer on the phase change memory material. The electrode layer includes a sidewall coating comprising ruthenium. Thus, embodiments may permit the electrode layer to have an improved mask retention when used as a mask during subsequent processing operations due to the presence of the sidewall coating.

Example 16: The limitation of any of claims 15 and 17-20, further comprising a barrier layer and a layer comprising ruthenium positioned between the phase change memory material and the electrode layer, the barrier layer positioned between the phase change memory material and the layer comprising ruthenium, the layer comprising ruthenium positioned between the barrier layer and the electrode layer. Thus embodiments allow for the formation of a barrier layer to protect underlying layers during processing operations. The layer comprising ruthenium may advantageously be used to forming the sidewall coating, which may provide desirable properties relating to mask retention during subsequent processing.

Example 17: The limitation of any of claims 15-16 and 18-20, further comprising wherein the electrode layer comprises tantalum nitride (TaN). Thus, embodiments allow for the use of tantalum nitride as an effective electrode layer material.

Example 18: The limitation of any of claims 15-17 and 19-20, further comprising wherein the barrier layer comprises carbon. Thus, embodiments allow for the use of carbon as an effective barrier layer material between the layer comprising ruthenium and the underlying layers.

Example 19: The limitation of any of claims 15-18 and 20, further comprising wherein the sidewall coating comprising ruthenium has a thickness in a range of 1 to 10 angstroms. Thus embodiments allow for the formation of a thin coating that protects the sidewall and enhances the ability of the existing layers to be used as a mask during subsequent processing operations.

Example 20: The limitation of any of claims 15-19, further comprising wherein the electrode layer comprises at least a portion of a top electrode, the phase change memory device further comprising a bottom electrode, the phase change memory material positioned between the top electrode and the bottom electrode, wherein the bottom electrode is free of the sidewall coating comprising ruthenium. Thus embodiments allow for the formation of a phase change memory device including a top electrode including a sidewall coating comprising ruthenium. Such a sidewall coating enabled the top electrode to act as at least a portion of a mask with improved mask retention properties during certain processing operations.

Certain embodiments relate to the formation of electronic devices including, but not limited to, memory devices utilizing phase change materials.

Electronic device materials including, for example, phase change materials, can be sensitive to processing operations including exposure to various gas species. The materials in the device may be subject to chemical and physical reactions and experience damage during operations such as etching and deposition. Further, the operations used during fabrication can damage one or more layers in the device. Damage to the phase change material can undesirably lead to changes in properties such as, for example, the crystallization temperature and composition. Such damage may impact the switching behavior of the phase change material. Minimizing the number of processing operations can lower the risk of damage.

Certain embodiments minimize the number of processing operations by using an organic planarization layer (OPL) having a protective coating thereon as a mask during subsequent processing operations. The protective coating improves the selectivity of the OPL during etching. Using the OPL as a mask during subsequent processing operations eliminates the need for forming a separate hard mask during processing, which can involve multiple operations including deposition and etching operations. By removing operations from the manufacturing process, the risk of damage to the underlying materials is lessened.

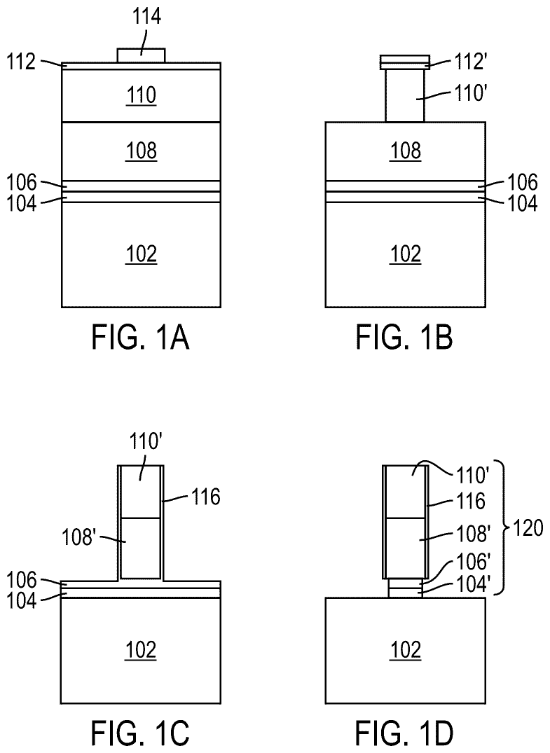

FIGS. 1A-1D illustrate cross-sectional views of various layers present and operations carried out during the formation of an electrode device including, but not limited to, a phase change memory (PCM) device. The illustrated layers in FIG. 1A include a stack 102 of device layers (not individually shown) that may include a substrate and one or more suitable device layers. A variety of suitable materials may be used in the stack 102. When a PCM device is being formed, the stack 102 may include one or more layers selected from a phase change material, buffer, selector, electrode, and/or etch stop layer. A variety of suitable materials may be used as the phase change material in the stack 102. Phase change materials may include, but are not limited to, one or more chalcogenide elements (e.g., sulfur(S), selenium (Se) and/or tellurium (Te)). Examples include, but are not limited to, chalcogenide alloys including Te with other elements such as antimony (Sb) and/or germanium (Ge), to form, for example, Sb₂Te₃, GeTe, and/or Ge₂Sb₂Te₅ (GST). Non-chalcogenide phase change materials may include, but are not limited to, gallium (Ga) and antimony (Sb) based alloys.

Above the stack 102, a thin buffer layer 104 may be formed. The buffer layer 104 may act to inhibit intermixing of materials with the PCM stack and may also act as an etch stop. In certain embodiments the buffer layer 104 may be formed to be approximately 5 nanometers (nm) to approximately 50 nm in height. Other heights are also possible. Suitable buffer layer materials include, but are not limited to, carbon (C), silicon carbide (SiC), silicon(S), tantalum (Ta), tantalum nitride (TaN), tantalum carbide (TaC), tungsten (W), tungsten nitride (WN), tungsten carbide (TiC), titanium (Ti), titanium nitride (TiN), and/or titanium carbide (TiC).

A layer 106 comprising ruthenium (Ru) may be formed on the buffer layer. In certain embodiments the layer 106 may be formed to be approximately 5 nanometers (nm) to approximately 20 nm in height. Other heights are also possible. The layer 106 comprising Ru may act as an etch stop layer and may act to provide rigidity to the stack. The layer 106 may also be used to form a sidewall protective layer on the sidewall of other layers during subsequent processing. By providing the sidewall protective layer including Ru, the various layers may act as a mask during subsequent etching operations.

A top electrode layer 108 may be formed on the layer 106. The top electrode layer 108 may be formed from any suitable material including, for example, TaN. Other top electrode layer 108 materials may include, but are not limited to: nitrides such as, for example, TiN, WN, and/or aluminum nitride (AlN); metals such as, for example, Ti, Ta, W, cobalt (Co), and/or aluminum (Al); and doped semiconductor materials that may be deposited using any suitable process such as chemical vapor deposition (CVD), physical vapor deposition (PVD), atomic layer deposition (ALD), sputtering, evaporation, electrochemical plating, etc. In certain embodiments the top electrode layer 108 may be formed to be approximately 50 nm to approximately 250 nm in height. Other heights are also possible.

Using suitable lithographic techniques, a lithographic stack including photoresist 114, silicon anti-reflective coating (SiARC) 112, and OPL) 110 may be formed on the top electrode layer 108. The OPL 110 may act as a planarization layer and may act as an etch stop. The OPL 110 may also act as a mask during processing of underlying layers. The SiARC layer 112 may be formed on the OPL 110, and above the SiARC layer 112, the photoresist 114 may be formed. As illustrated in FIG. 1A, the photoresist 114 has been patterned.

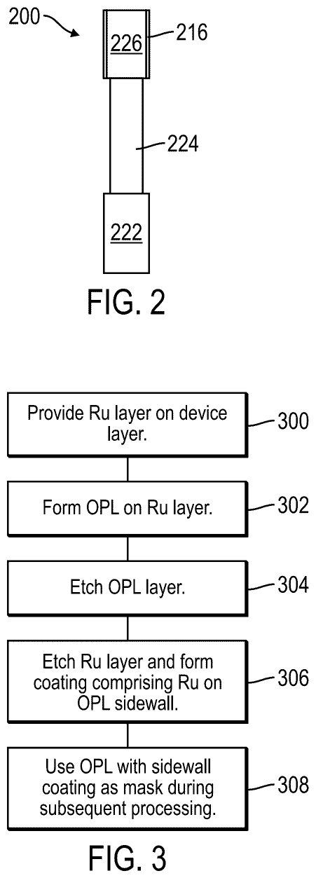

One or more etching operations may be carried out to remove portions of the SiARC layer 112 and the OPL 110, as illustrated in FIG. 1B. In certain embodiments the etching is controlled to form a pillar-like structure including the remaining portion 110′ of the OPL 110, the remaining portion 112′ of the SiARC layer 112, and the patterned photoresist layer 114. The remaining portion 110′ may be etched so that it undercuts the SiARC remaining portion 112′, as illustrated in FIG. 2B. By forming the remaining portion 110′ to have a smaller width than the remaining portion 112′, the critical dimension of the underlying electrode layer 108 using the remaining portion 110′ as a mask can also be formed to be smaller.

One or more additional etching operations may be carried out to etch the top electrode layer 108 and the layer 106 using the remaining portion 110′ as a mask, to form a remaining portion 108′ of the top electrode layer 108 as illustrated in FIG. 1C. The etching may be carried out in a plasma chamber using a suitable gas mixture, including, but not limited to, a halogen gas and an inert gas, so that both chemical and physical etching may be carried out. The physical etching may be controlled so that an amount of sputtered Ru material from the layer 106 is redeposited on sidewalls of the remaining portion 110′ of the OPL 110 and the remaining portion 108′ of the top electrode layer 108 as sidewall coating 116. The sidewall coating 116 may also include an amount of the material of the top electrode layer 108 mixed with sputtered Ru material from the layer 106. The etching operations may include plasma etching in one or more operations, with certain embodiments including a suitable gas mixture including, but not limited to, a halogen gas for chemical etching, inert ions for physical sputtering, and a passivating gas. One such embodiment utilizes, for example, a halogen gas including chlorine, an inert gas including argon, and a passivating gas including oxygen.

As illustrated in FIG. 1C, the layer 106 on the buffer layer 104 was not fully etched. Additional etching may be carried out to further etch the layer 106 comprising Ru and the buffer layer 104, to form remaining portion 106′ and remaining portion 104′, to reach the stack 102 therebelow. The etching may in certain embodiments be suitably controlled so that portions of one or both of the remaining portion 106′ and buffer layer remaining portion 104′ are undercut, as illustrated in FIG. 1D. By forming the remaining portion 106′ and the remaining portion 104′ to have a smaller width (as illustrated in FIG. 1D), the critical dimension of the underlying stack 102 can also be formed to be smaller during subsequent processing.

In certain embodiments the resultant structure 120 may be pillar-shaped and include the coating 116 comprising Ru deposited on the sidewalls of the remaining portion 110′ of the OPL 110 and remaining portion 108′ of the top electrode layer 108. It is noted that in certain embodiments the pillar-shaped structure 120 may be cylindrical in shape. The sidewall coating 116 of the remaining portion 110′ may also include some sputtered material from the top electrode layer 108 that is co-deposited, together with the Ru, on the remaining portion 110′ sidewall. For example, in an embodiment utilized TaN as the top electrode layer 108, the sidewall coating 116 may include Ta and Ru intermixed. The coating 116 having multiple materials may provide desirable properties relating to mask retention during subsequent operations. In certain embodiments, the coating 116 deposited on the sidewall of the remaining portion 110′ may include a thickness in the range of approximately 1 angstrom to approximately 10 angstroms. Other thicknesses are also possible. The remaining portion 106′ and the buffer layer remaining portion 104′ may also be part of the pillar-shaped structure 120.

Subsequent etching may be carried out using the pillar-like structure 120 including the remaining portion 110′ of the OPL 110 and underlying layers as a mask. The sidewall coating 116 including Ru acts to reinforce the remaining portion 110′ and the remaining portion 108′ during subsequent etching of the stack 102. After subsequent processing of the underlying layer or layers, any remaining portion 110′ of the OPL 110 may be removed from the structure using a suitable operation such as etching, to leave an electrode structure. In certain embodiments, the subsequent processing of the underlying layer or layers may be carried out using a suitable plasma etching process that consumes the remaining portion 110′ of the OPL 110 during the subsequent processing, leaving an electrode structure made up primarily of the remaining portion 108′ of the top electrode layer 108 together with the underlying thin layers of the remaining portion 106′ of the layer comprising Ru 106 and the remaining portion 104′ of the buffer layer 104. A quantity of the coating 116 comprising Ru may also be present on the sidewall of the remaining electrode layer 108′. Processing efficiency may be gained by using the OPL remaining portion 110′, including the protective sidewall coating 116, as a mask, because additional deposition and etching operations may not be necessary.

In other embodiments one or more of the layers in the electrode structure may be omitted and other layers changed in size. For example, the layer 106′ could be formed to be taller in height and be used as the primary electrode material layer, to take the place of the layer 108′.

Other processes for forming devices including, but not limited to, phase change memory devices, typically utilize an additional hard mask layer, such as TiN, between the top electrode layer 108 and the OPL layer 110. Such a hard mask layer is typically used for patterning the top electrode layer 108. By using the remaining portion 110′ of the OPL 110 with the protective sidewall coating 116 as a masking layer, the deposition and later removal operations associated with the use of an additional mask layer may be eliminated from the process, leading to faster and more efficient processing. In certain embodiments the remaining portion 110′ and the remaining portion 108′, with the protective sidewall coating 116, may be used as a mask during multiple subsequent processing operations on underlying layers including layer(s) in the stack 102. The remaining portion 110′ may be removed during or after its use as a mask.

FIG. 2 illustrates a cross-sectional view of a phase change memory device 200 in accordance with certain embodiments, including a top electrode 226, bottom electrode 222, and stack 224 therebetween. The top electrode 226 may include a protective sidewall coating 216 of a material comprising Ru such as the coating 116 described above. The bottom electrode 222 is free of such a protective sidewall coating. At least some of the operations described above in connection with FIGS. 1A-1D may be carried out for forming the device 200 in accordance with certain embodiments. The stack 224 as processed may include one or more suitable layers including, but not limited to, a phase change memory material, buffer, selector, and/or etch stop layers that have been etched to a desired critical dimension.

In the embodiment of FIG. 2, the device 200 may be formed using the top electrode 226, together with a previously present OPL layer having a protective sidewall coating 216 which may be similar to the coating 116 described above, as a mask while forming the stack 224. The OPL having the protective sidewall coating is no longer present in the device 200 as illustrated in FIG. 2. Some of the thickness of the protective sidewall coating may have been removed during the processing operations, so that the sidewall coating 216 thickness on the device 200 may be smaller than when originally formed. As a result of the top electrode 226 being used as a mask for processing the stack 224, it was not necessary for the bottom electrode 222 to be used as a mask for processing the stack 224 and as a result, the bottom electrode 222 may be formed without a sidewall protective coating.

FIG. 3 illustrates a flowchart including operations in a process for forming an electronic device using an OPL with a protective sidewall coating, which may be used as a mask during subsequent processing. For forming the device, a layer comprising Ru is provided (at block 300) on a device layer. An OPL may be formed (at block 302) on the Ru layer. The OPL is patterned and etched (at block 304) using, for example, suitable lithographic techniques. The Ru layer is etched and a coating comprising a quantity of material from the Ru layer is formed (at block 306) on the OPL sidewall. Such etching may be carried out in a plasma chamber as described above. The OPL with the protective sidewall coating may be used as a mask for subsequent processing (at box 308) such as etching.

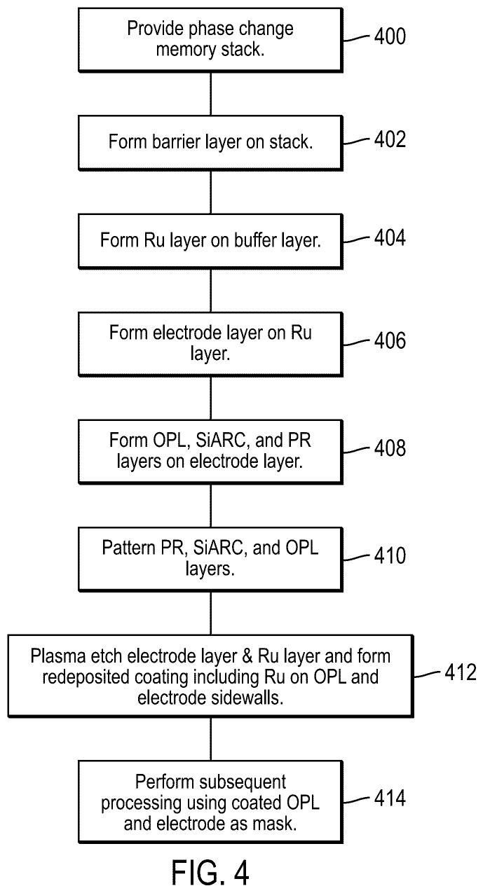

FIG. 4 illustrates a flowchart including operations in a process for forming an electronic devices using an OPL on an electrode, with a protective sidewall coating, which may be used as a mask during subsequent processing of a phase change memory stack that includes at least a layer of a phase change material. For forming the device, a phase change memory stack is provided (at block 400). A buffer layer such as, for example, carbon, may be provided on the stack (at block 402) to inhibit interactions between the layers above and below the buffer layer. A layer comprising Ru is provided on the barrier layer (at block 404). An electrode material layer is provided on the Ru layer (at block 406). OPL, SiARC, and PR layers are formed (at block 408) on the electrode material layer. The PR, SiARC, and OPL layers are patterned (at block 410) using suitable techniques. A plasma etch operation is then carried out on the electrode material layer and the Ru layer (at block 412), wherein a coating comprising Ru is formed on the sidewall of the OPL and electrode material layer. Subsequent processing of the PCM stack including, but not limited to, etching, may be carried out using the coated OPL and electrode material (at block 414) as a mask.

At least some of the operations in the flowcharts of FIGS. 3-4 may be carried out as described above, for example, in connection with the other figures.

With certain described embodiments, by forming an OPL having a protective coating thereon, the layer can be used as a mask during subsequent processing operations such as etching. Ruthenium is an effective material for use in the protective coating. The protective coating acts as a fencing around the OPL and improves the mask retention properties. Using the OPL as a mask during subsequent processing operations eliminates the need for forming an additional hard mask, which is typically a hard dielectric layer. The OPL with protective coating may be used as a mask when patterning the electrode layer, and the OPL with protective coating and the patterned electrode layer may be used as a mask when processing underlying layers such as, for example, a phase change material layer. By removing operations from the manufacturing process relating to the formation and removal of an additional hard mask layer, the risk of damage to the underlying materials is decreased.

As described above, certain embodiments may relate to forming phase change memory devices. Such devices may form the memory cells of a 3D crosspoint memory or other type of non-volatile storage device.

Embodiments described herein may be used in the manufacture of integrated circuits. The resulting integrated circuit chips can be distributed by the fabricator in raw wafer form (i.e., a single wafer with multiple unpackaged chips), bare die, or packaged form. In the latter case, the chip is placed in a single-chip package (e.g., a plastic carrier with leads attached to a motherboard or other higher-level carrier) or in a multi-chip package (e.g., a ceramic carrier with surface interconnects and/or or buried connections). In either case, the chip is then integrated with other chips, discrete circuit elements, and/or other signal processing devices as part of either (a) an intermediate product, such as a motherboard, or (b) an end product. The end product can be any product that contains integrated circuit chips, ranging from toys and other simple applications to advanced computer products with a display, keyboard or other input device, and a central processor.

The terminology used herein is for the purpose of describing particular embodiments only and is not intended to be limiting of the invention. As used herein, the singular forms “a”, “an” and “the” include the plural forms as well, unless the context clearly indicates otherwise. It is further understood that the terms “comprises” and/or “comprising” and variations thereof mean “including, but not limited to”, unless expressly specified otherwise. “Optional” means that the event or circumstance described may or may not occur and that the description includes instances where the event occurs and instances where it does not occur. The enumerated listing of items does not imply that any or all of the items are mutually exclusive, unless expressly specified otherwise.

A description of an embodiment with several components in communication with each other does not necessarily imply that all such components are required in all embodiments. When a single device or article is described herein, it will be readily apparent that more than one device or article (whether or not they cooperate) may be used in certain embodiments in place of a single device or article. Similarly, where more than one device or article is described herein (whether or not they cooperate), it will be readily apparent that a single device or article may be used in certain embodiments in place of the more than one device or article, or a different number of devices or articles may be used instead of the shown number of devices or articles. The functionality and/or the features of a device may be alternatively embodied by one or more other devices which are not explicitly described as having such functionality and/or features.

Approximate formulations, as used herein, may be used to modify any quantitative representation that is permissible may vary without leading to a change in the basic function to which it relates. Accordingly, a value modified by one or more of the terms “about,” “approximately,” and “substantially” is not limited to the precise value specified. In at least some cases, the approximate formulation may correspond to the accuracy of an instrument used to measure the value. Here and throughout the specification and claims, range boundaries may be combined and/or interchanged; such areas are identified and include all sub-areas therein, unless the context or language indicates otherwise.

In discussing the present technology, it may be helpful to describe various salient terms. In one aspect, spatially related terminology such as “front,” “back,” “top,” “bottom,” “beneath,” “below,” “lower,” above,” “upper,” “side,” “left,” “right,” and the like, is used with reference to the direction of the Figures being described. Since components of embodiments of the disclosure can be positioned in a number of different directions, the directional terminology is used for purposes of illustration and is in no way limiting. Thus, it will be understood that the spatially relative terminology is intended to encompass different directions of the device in use or operation in addition to the direction depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other directions) and the spatially relative descriptors used herein should be interpreted accordingly.

As used herein, the terms “coupled” and/or “electrically coupled” are not meant to mean that the elements must be directly coupled together—intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Aspects of the present invention may be described herein with reference to flowchart illustrations and/or block diagrams according to embodiments of the invention. Individual blocks may be optional, and the order of blocks may be varied. Inventive subject matter may be found in each block individually or in groups of the blocks. It will be understood that each block of the flowchart illustrations and/or block diagrams, and combinations of blocks in the flowchart illustrations and/or block diagrams, can be implemented by a machine system to manufacture and implement embodiments as described herein.

Example embodiments may be described herein with reference to cross-sectional views that are schematic illustrations of idealized or simplified embodiments (and intermediate structures). As such, for certain features, there may be variations from the shapes of the features in the illustrations as a result, for example, of manufacturing techniques and/or tolerances. Thus, the regions illustrated in the figures may be schematic in nature and their shapes do not necessarily illustrate the actual shape of a region of a device and do not limit the scope.

It is to be understood that other embodiments may be used and structural or logical changes may be made without departing from the spirit and scope defined by the claims. The description of the present disclosure and embodiments therein has been presented for purposes of illustration and description, but is not intended to be exhaustive or limited to the disclosure in the form disclosed. Modifications and variations will be apparent to those of ordinary skill in the art, and structure or logical changes may be made without departing from the scope and spirit of the disclosure. In particular, elements of the embodiments described hereinafter may be combined with elements of different embodiments. Embodiments have been chosen and described in order to best explain the principles of the disclosure and the practical application, and to enable others of ordinary skill in the art to understand the disclosure for various embodiments with various modifications as are suited to the particular use contemplated.

What is claimed:

1. A method for forming an electronic device, comprising:
providing a layer comprising ruthenium on a device layer;
forming an organic planarization layer on the layer comprising ruthenium, wherein the layer comprising ruthenium is positioned between the device layer and the organic planarization layer; and
performing one or more etching operations to etch part of the organic planarization layer to form a remaining portion of the organic planarization layer and to etch part of the layer comprising ruthenium to form a remaining portion of the layer comprising ruthenium, wherein the one or more etching operations to etch part of the layer comprising ruthenium further comprises forming a coating comprising ruthenium from the layer comprising ruthenium on a sidewall of the remaining portion of the organic planarization layer.

2. The method of claim 1, further comprising:
forming an electrode layer on the layer comprising ruthenium so that the electrode layer is positioned between the layer comprising ruthenium and the organic planarization layer; and
etching the electrode layer, wherein the coating comprising ruthenium on the sidewall of the remaining portion of the organic planarization layer further includes a material of the electrode layer.

3. The method of claim 2, further comprising forming the coating comprising ruthenium on a sidewall of the electrode layer.

4. The method of claim 1, wherein the coating comprising ruthenium has a thickness in a range of 1 angstrom to 10 angstroms.

5. The method of claim 2, further comprising forming a barrier layer between the device layer and the layer comprising ruthenium.

6. The method of claim 5, wherein the barrier layer comprises carbon.

7. The method of claim 6, wherein the electrode layer comprises tantalum nitride.

8. A method for forming an electronic device, comprising:
providing a layer comprising ruthenium on a device layer;
forming an electrode layer on the layer comprising ruthenium;
forming an organic planarization layer on the electrode layer;
etching part of the organic planarization layer to form a remaining portion of the organic planarization layer; and
etching part of the electrode layer and part of the layer comprising ruthenium to form a remaining portion of the electrode layer and a remaining portion of the layer comprising ruthenium, wherein the etching part of the electrode layer and part of the layer comprising ruthenium further comprises forming a coating comprising ruthenium from the layer comprising ruthenium on a sidewall of the remaining portion of the organic planarization layer.

9. The method of claim 8, wherein the etching part of the electrode layer and part of the layer comprising ruthenium further comprises forming the coating on the sidewall of the remaining portion of the organic planarization layer to include a material from the electrode layer.

10. The method of claim 8, further comprising forming the coating comprising ruthenium on a sidewall of the remaining portion of the electrode layer.

11. The method of claim 8, further comprising forming the coating comprising ruthenium to have a thickness in a range of from 1 angstrom to 10 angstroms.

12. The method of claim 8, wherein the device layer comprises a barrier layer on a phase change memory material layer.

13. The method of claim 8, wherein the etching part of the electrode layer and part of the layer comprising ruthenium comprises performing a plamsa etching operation including a chemical reaction and physical sputtering.

14. The method of claim 13, wherein the plasma etching operation includes using a plurality of gases including chlorine, oxygen, and argon.

15. A phase change memory device comprising:
a phase change memory material; and
an electrode layer on the phase change memory material, the electrode layer including a sidewall coating comprising ruthenium.

16. The phase change memory device of claim 15, further comprising a barrier layer and a layer comprising ruthenium positioned between the phase change memory material and the electrode layer, the barrier layer positioned between the phase change memory material and the layer comprising ruthenium, the layer comprising ruthenium positioned between the barrier layer and the electrode layer.

17. The phase change memory device of claim 16, wherein the electrode layer comprises tantalum nitride.

18. The phase change memory device of claim 17, wherein the barrier layer comprises carbon.

19. The phase change memory device of claim 15, wherein the sidewall coating comprising ruthenium has a thickness in a range of 1 to 10 angstroms.

20. The phase change memory device of claim 15, wherein the electrode layer comprises at least a portion of a top electrode, the phase change memory device further comprising a bottom electrode, the phase change memory material positioned between the top electrode and the bottom electrode, wherein the bottom electrode is free of the sidewall coating comprising ruthenium.
